(19) United States
(12) Patent Application Publication
(10) Pub. No.: US 2024/0324382 A1
(43) Pub. Date: Sep. 26, 2024

(54) DISPLAY APPARATUS

(71) Applicant: Samsung Display Co., Ltd., Yongin-si (KR)

(72) Inventors: Donghee Shin, Yongin-si (KR); Sunkwun Son, Yongin-si (KR)

(21) Appl. No.: 18/604,291

(22) Filed: Mar. 13, 2024

(30) Foreign Application Priority Data
Mar. 24, 2023 (KR) 10-2023-0038989
Jul. 18, 2023 (KR) 10-2023-0093338

(51) Int. Cl. H10K 59/35; H10K 59/121; H10K 59/131

(52) U.S. Cl. CPC H10K 59/353; H10K 59/1213; H10K 59/131

(57) ABSTRACT

A display apparatus includes a first sub-pixel including a first lower metal, a first semiconductor layer on the first lower metal, and a first upper metal on the first semiconductor layer; a second sub-pixel including a second lower metal, a second semiconductor layer on the second lower metal, and a second upper metal on the second semiconductor layer; and a third sub-pixel including a third lower metal, a third semiconductor layer on the third lower metal, and a third upper metal on the third semiconductor layer, wherein an interval between the second lower metal and the first semiconductor layer is greater than an interval between the second semiconductor layer and the first semiconductor layer in a plan view, and wherein a first sub-pixel, a second sub-pixel, and a third sub-pixel configured to display light of different colors.

### CROSS-REFERENCE TO RELATED APPLICATIONS

The present application claims priority to and the benefit of Korean Patent Application No. 10-2023-0038989, filed on Mar. 24, 2023, and Korean Patent Application No. 10-2023-0093338, filed on Jul. 18, 2023, in the Korean Intellectual Property Office, the entire contents of which are herein incorporated by reference.

### BACKGROUND

### 1. Field

Aspects of embodiments of the present disclosure relate to a display apparatus, and more particularly, to a display apparatus capable of displaying high-quality images.

### 2. Description of Related Art

Generally, in a display apparatus such as an organic light-emitting display apparatus, thin-film transistors, connection electrodes, and wirings are arranged in each (sub) pixel to control brightness and the like of each (sub) pixel. The thin-film transistors, the connection electrodes, and the wirings form a multi-layered structure.

Configuration of a plurality of sub-pixels, each configured to emit light of a different color, is an important consideration for displaying high-quality images.

### SUMMARY

Aspects of some embodiments of the present disclosure are directed to a display apparatus capable of displaying high-quality images through the configuration and array of a plurality of sub-pixels.

However, such a technical objective is just an example, and the disclosure is not limited thereto.

Additional aspects will be set forth in part in the description which follows and, in part, will be apparent from the description, or may be learned by practice of the presented embodiments of the disclosure.

According to some embodiments, there is provided a display apparatus including: a first sub-pixel including a first lower metal, a first semiconductor layer on the first lower metal, and a first upper metal on the first semiconductor layer; a second sub-pixel including a second lower metal, a second semiconductor layer on the second lower metal, and a second upper metal on the second semiconductor layer; and a third sub-pixel including a third lower metal, a third semiconductor layer on the third lower metal, and a third upper metal on the third semiconductor layer, wherein an interval between the second lower metal and the first semiconductor layer is greater than an interval between the second semiconductor layer and the first semiconductor layer in a plan view, and wherein a first sub-pixel, a second sub-pixel, and a third sub-pixel configured to display light of different colors.

In some embodiments, the interval between the second lower metal and the first semiconductor layer is less than an interval between the second lower metal and the first lower metal.

In some embodiments, the first lower metal, the second lower metal, and the third lower metal are arranged side-by-side in a second direction perpendicular to a first direction.

In some embodiments, the first sub-pixel further includes a first pixel electrode, the second sub-pixel further includes a second pixel electrode, and the third sub-pixel further includes a third pixel electrode, and the second pixel electrode partially overlaps at least one of the first lower metal and the third lower metal.

In some embodiments, the first pixel electrode, the second pixel electrode, and the third pixel electrode are arranged side-by-side in a third direction crossing the first direction and the second direction.

In some embodiments, the first pixel electrode is electrically connected to the first semiconductor layer through a first contact hole, the second pixel electrode is electrically connected to the second semiconductor layer through a second contact hole, and the third pixel electrode is electrically connected to the third semiconductor layer through a third contact hole.

In some embodiments, the second lower metal is electrically connected to a gate connection line through a fourth contact hole, and the gate connection line is surrounded by the second semiconductor layer.

In some embodiments, the first to third upper metals and the gate connection line are at a same layer.

In some embodiments, the first upper metal at least partially overlaps the first lower metal and the first semiconductor layer, the second upper metal at least partially overlaps the second lower metal and the second semiconductor layer, and the third upper metal at least partially overlaps the third lower metal and the third semiconductor layer.

In some embodiments, each of the first to third upper metals extends in the second direction, and one end of at least one of the first to third upper metals extends in the first direction.

In some embodiments, an interval between the second lower metal and the third semiconductor layer is greater than an interval between the second semiconductor layer and the third semiconductor layer and less than an interval between the second lower metal and the third lower metal.

In some embodiments, each of the first to third lower metals has a gate electrode of a driving transistor.

In some embodiments, the first upper metal is electrically connected to the first semiconductor layer through a fifth contact hole, the second upper metal is electrically connected to the second semiconductor layer through a sixth contact hole, and the third upper metal is electrically connected to the third semiconductor layer through a seventh contact hole.

In some embodiments, the first sub-pixel further includes a first sub-lower metal arranged between the first lower metal and the second lower metal and electrically connected to the first semiconductor layer, and the third sub-pixel further includes a third sub-lower metal arranged between the second lower metal and the third lower metal and electrically connected to the third semiconductor layer.

According to some embodiments, there is provided a display apparatus including: a first sub-pixel includes a first lower metal having a gate electrode of a first driving transistor, and a first semiconductor layer on the first lower metal, a second sub-pixel includes a second lower metal having a gate electrode of a second driving transistor, and a second semiconductor layer on the second lower metal, a third sub-pixel includes a third lower metal having a gate electrode of a third driving transistor, and a third semiconductor layer on the third lower metal, wherein a first sub-pixel, a second sub-pixel, and a third sub-pixel configured to respectively display light of different colors, wherein the first to third lower metals are arranged side-by-side in a second direction perpendicular to a first direction, and wherein a width in the second direction of the second lower metal is less than a width in the second direction of the second semiconductor layer.

In some embodiments, the second lower metal is electrically connected to a gate connection line through a fourth contact hole, the gate connection line being surrounded by the second semiconductor layer.

In some embodiments, the first sub-pixel further includes a first pixel electrode, the second sub-pixel further includes a second pixel electrode, and the third sub-pixel further includes a third pixel electrode, and the second pixel electrode partially overlaps at least one of the first lower metal and the third lower metal.

In some embodiments, the first sub-pixel further includes a first sub-lower metal arranged between the first lower metal and the second lower metal and electrically connected to the first pixel electrode, and the third sub-pixel further includes a third sub-lower metal arranged between the second lower metal and the third lower metal and electrically connected to the second pixel electrode.

In some embodiments, the first sub-pixel further includes a first upper metal partially overlapping the gate electrode of the first driving transistor and on the first semiconductor layer, the second sub-pixel further includes a second upper metal partially overlapping the gate electrode of the second driving transistor and on the second semiconductor layer, and the third sub-pixel further includes a third upper metal partially overlapping the gate electrode of the third driving transistor and on the third semiconductor layer.

In some embodiments, a width in the second direction of the first lower metal is less than a width in the second direction of the first semiconductor layer, and a width in the second direction of the third lower metal is less than a width in the second direction of the third semiconductor layer.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to some embodiments of the present disclosure;

FIG. 2A is a schematic conceptual view of a portion of the display apparatus of FIG. 1, according to some embodiments of the present disclosure;

FIG. 2B is a view showing a color converting portion of FIG. 2A, according to some embodiments of the present disclosure;

FIG. 3 is a schematic equivalent circuit diagram of a light-emitting diode corresponding to one pixel of a display apparatus and a sub-pixel circuit connected thereto according to some embodiments of the present disclosure;

FIG. 4 is a schematic configuration view of the positions of transistors, a storage capacitor, and the like in a pixel of a display apparatus according to some embodiments of the present disclosure;

FIGS. 5 to 8 are schematic configuration views of elements such as transistors and a storage capacitor, for each layer, of a display apparatus shown in FIG. 4, according to some embodiments of the present disclosure;

FIG. 9 is a schematic cross-sectional view of the display apparatus, taken along the line I-I′ of FIG. 4, according to some embodiments of the present disclosure;

FIG. 10 is a schematic cross-sectional view of the display apparatus, taken along the line II-II′ of FIG. 4, according to some embodiments of the present disclosure;

FIG. 11 is a schematic cross-sectional view of the display apparatus, taken along the line III-III′ of FIG. 4, according to some embodiments of the present disclosure;

FIG. 12 is a schematic configuration view of the positions of transistors, a storage capacitor, and the like in a pixel of a display apparatus according to some embodiments of the present disclosure; and

FIGS. 13 to 15 are schematic configuration views of elements such as transistors and a storage capacitor, for each layer, of a display apparatus shown in FIG. 12, according to some embodiments of the present disclosure.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As the disclosure allows for various suitable changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various suitable forms.

Hereinafter, embodiments will be described with reference to the accompanying drawings, wherein like reference numerals refer to like elements throughout and a repeated description thereof is omitted.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

An X-axis, a Y-axis and a Z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially and performed in the opposite order.

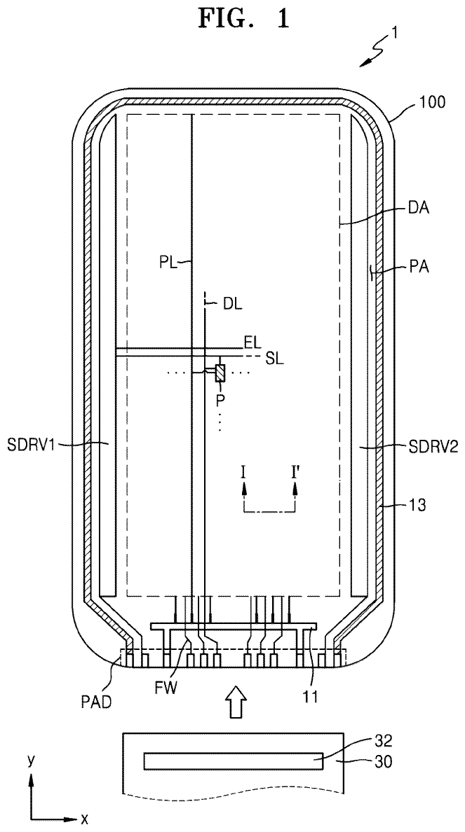

FIG. 1 is a schematic plan view of a display apparatus 1 according to some embodiments of the present disclosure.

Referring to FIG. 1, various kinds of elements constituting the display apparatus 1 are disposed over a substrate 100. The substrate 100 may include a display area DA and a peripheral area PA surrounding the display area DA. The display area DA may be protected from external air, moisture, or the like by being covered by an encapsulation member.

Sub-pixels are arranged in the display area DA of the substrate 100. The sub-pixels may each be configured to display images using light emitted from a display element such as a light-emitting diode. Each light-emitting diode may be configured to emit, for example, red, green, or blue light.

Each light-emitting diode may be electrically connected to a sub-pixel circuit, and each sub-pixel circuit may include transistors and a storage capacitor. Sub-pixel circuits may each be electrically connected to peripheral circuits arranged in the peripheral area PA. The peripheral circuits arranged in the peripheral area PA may include a first scan driving circuit SDRV1, a second scan driving circuit SDRV2, a terminal part PAD, a driving voltage supply line 11, and a common voltage supply line 13.

The first scan driving circuit SDRV1 may be configured to apply scan signals to each of the sub-pixel circuits through a scan line SL, the sub-pixel circuits corresponding to the sub-pixels. The first scan driving circuit SDRV1 may be configured to apply emission control signals to each sub-pixel circuit through an emission control line EL. The second scan driving circuit SDRV2 may be arranged opposite the first scan driving circuit SDRV1 with the display area DA therebetween and be approximately parallel to the first scan driving circuit SDRV1. Some of the sub-pixel circuits may be electrically connected to the first scan driving circuit SDRV1, and the rest may be electrically connected to the second scan driving circuit SDRV2. In some examples, the second scan driving circuit SDRV2 may be omitted.

The terminal part PAD may be arranged on one side of the substrate 100. The terminal part PAD may be exposed and connected to a display circuit board 30 by not being covered by an insulating layer. A display driver 32 may be disposed on the display circuit board 30.

The display driver 32 may be configured to generate control signals transferred to the first scan driving circuit SDRV1 and the second scan driving circuit SDRV2. The display driver 32 may be configured to generate data signals, and the generated data signals may be transferred to the sub-pixel circuits through fan-out wirings FW and data lines DL connected to the fan-out wirings FW.

The display driver 32 may be configured to supply a driving voltage ELVDD to the driving voltage supply line 11 and supply a common voltage ELVSS to the common voltage supply line 13. The driving voltage ELVDD may be applied to the pixel circuits of the pixels P through a driving voltage line PL connected to the driving voltage supply line 11, and the common voltage ELVSS may be connected to the common voltage supply line 13 and applied to an opposite electrode of the display element.

The driving voltage supply line 11 may extend in an x direction below the display area DA. The common voltage supply line 13 may have a loop shape having one open side to partially surround the display area DA.

The display apparatus 1 of FIG. 1 is a portable electronic apparatus for displaying moving images or still images and may include portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like. Alternatively, the display apparatus 1 may be used as a display screen of various products such as televisions, notebook computers, monitors, advertisement boards, Internet of things (IoTs), and the like. In addition, the display apparatus 1 according to some examples may be used in wearable devices including smartwatches, watchphones, glasses-type displays, and head-mounted displays (HMDs). In addition, in some examples, the display apparatus 1 may be used as a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

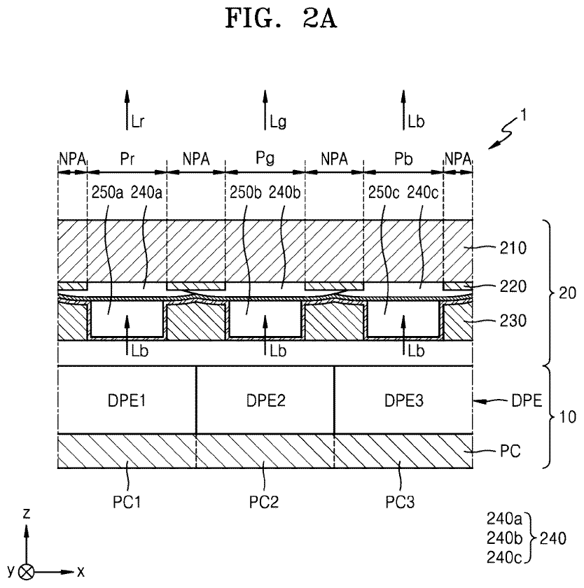

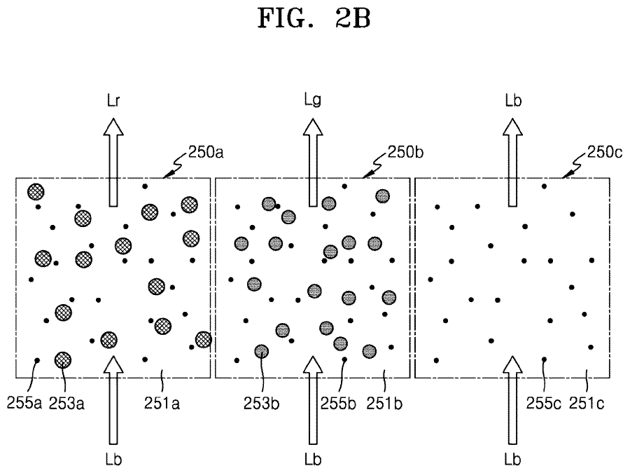

FIG. 2A is a schematic conceptual view of a portion of the display apparatus 1 of FIG. 1, according to some embodiments of the present disclosure. FIG. 2B is a view showing a color converting portion of FIG. 2A, according to some embodiments of the present disclosure.

The display apparatus 1 may include a light-emitting panel 10 and a filter panel 20 that are stacked as shown in FIG. 2. The light-emitting panel 10 may include a plurality of display elements DPE. Each of the display elements DPE is electrically connected to a circuit PC (referred to as a pixel circuit, hereinafter) corresponding thereto. The display elements DPE and the pixel circuits PC may be arranged in the display area DA.

In some embodiments, the display elements DPE include a first display element DPE1, a second display element DPE2, and a third display element DPE3. Each of the first display element DPE1, the second display element DPE2, and the third display element DPE3 may be electrically connected to the pixel circuit PC and driven by the pixel circuit PC.

Each of the first display element DPE1, the second display element DPE2, and the third display element DPE3 may be configured to emit light. In some embodiments, the first display element DPE1, the second display element DPE2, and the third display element DPE3 are configured to emit the same light. As an example, each of the first display element DPE1, the second display element DPE2, and the third display element DPE3 may be configured to emit one of red light Lr, green light Lg, and blue light Lb. As another example, each of the first display element DPE1, the second display element DPE2, and the third display element DPE3 may be configured to emit one of red light Lr, green light Lg, blue light Lb, and white light. In some other embodiments, at least one of the first display element DPE1, the second display element DPE2, and the third display element DPE3, and another of the first display element DPE1, the second display element DPE2, and the third display element DPE3 are configured to emit different light from other ones of the same. As an example, the first display element DPE1 may be configured to emit red light Lr, the second display element DPE2 may be configured to emit green light Lg, and the third display element DPE3 may be configured to emit blue light Lb. Hereinafter, the case where all of the first display element DPE1, the second display element DPE2, and the third display element DPE3 are configured to emit blue light Lb is mainly described in detail.

The filter panel 20 may be disposed on the light-emitting panel 10. The filter panel 20 may be configured to change the wavelength of light emitted from the light-emitting panel 10. In some embodiments, the filter panel 20 is disposed on the display element DPE. The filter panel 20 may be configured to change the wavelength of light emitted from the display element DPE. In some embodiments, blue light Lb emitted from the first display element DPE1, the second display element DPE2, and the third display element DPE3 is converted to red light Lr, green light Lg, or blue light or transmitted (e.g., without being filtered) while passing through the filter panel 20. A region from which red light Lr is emitted may correspond to a red sub-pixel Pr. A region from which green light Lg is emitted may correspond to a green sub-pixel Pg. A region from which blue light Lb is emitted may correspond to a blue sub-pixel Pb.

The filter panel 20 may include an upper substrate 210, a first light-blocking layer 220, a second light-blocking layer 230, a filter 240, a first color converting portion 250a, a second color converting portion 250b, and a third color converting portion 250c. The first light-blocking layer 220 may include a plurality of holes formed while portions of the red sub-pixel Pr, the green sub-pixel Pg, and the blue sub-pixel Pb are removed. The first light-blocking layer 220 may include a material portion overlapping a non-pixel area NPA, and the material portion may include various suitable materials that may absorb light.

The second light-blocking layer 230 may be disposed on the first light-blocking layer 220. The second light-blocking layer 230 may include a material portion overlapping the non-pixel area NPA, and the material portion may include various suitable materials that may absorb light. The second light-blocking layer 230 may include the same material as the first light-blocking layer 220 or include a different material. In some embodiments, the first light-blocking layer 220 and/or the second light-blocking layer 230 include an opaque inorganic insulating material such as chromium oxide or molybdenum oxide, or an opaque organic insulating material such as black resin.

The filter 240 may include a first filter 240a, a second filter 240b, and a third filter 240c. The first filter 240a may include pigment or dye of a first color (e.g., red). The second filter 240b may include pigment or dye of a second color (e.g., green). The third filter 240c may include pigment or dye of a third color (e.g., blue).

The first color converting portion 250a, the second color converting portion 250b, and the third color converting portion 250c may be disposed between the filter 240 and the display element DPE.

The first color converting portion 250a may overlap the first filter 240a and convert incident blue light Lb to red light Lr. The first color converting portion 250a may include a first photosensitive polymer 251a, first quantum dots 253a, and first scattering particles 255a. The first quantum dots 253a and the first scattering particles 255a may be dispersed in the first photosensitive polymer 251a.

The first quantum dots 253a may be excited by blue light Lb and configured to emit red light Lr having a longer wavelength than the incoming blue light Lb. The first photosensitive polymer 251a may include a light-transmissive organic material. The first scattering particles 255a may increase the color-converting efficiency of the first color converting portion 250a by scattering blue light Lb not absorbed in the first quantum dots 253a and allowing more first quantum dots 253a to be excited. The first scattering particles 255a may be, for example, titanium oxide (TiO₂), metal particles, and/or the like. The first quantum dots 253a may be one of a Group II-Group VI compound, a Group III-Group V compound, a Group IV-Group VI compound, a Group IV element, a Group IV compound, and a combination thereof.

The second color converting portion 250b may overlap the second filter 240b and convert incident blue light Lb to green light Lg. The second color converting portion 250b may include a second photosensitive polymer 251b, second quantum dots 253b, and second scattering particles 255b. The second quantum dots 253b and the second scattering particles 255b may be dispersed in the second photosensitive polymer 251b.

The second quantum dots 253b may be excited by blue light Lb and configured to emit green light Lg having a longer wavelength than the blue light Lb. The second photosensitive polymer 251b may include a light-transmissive organic material. The second scattering particles 255b may increase a color-converting efficiency by scattering blue light Lb not absorbed in the second quantum dots 253b and allowing more second quantum dots 253b to be excited. The second scattering particles 255b may be, for example, titanium oxide (TiO₂), metal particles, and/or the like. The second quantum dots 253b may be one of a Group II-Group VI compound, a Group III-Group V compound, a Group IV-Group VI compound, a Group IV element, a Group IV compound, and a combination thereof. The size of the quantum dot may be several nanometer, and the wavelength of light after conversion may change depending on the size of the quantum dot.

The third color converting portion 250c may overlap the third filter 240c and transmit incident blue light Lb. The third color converting portion 250c may include a third photosensitive polymer 251c and third scattering particles 255c. The third scattering particles 255c may be dispersed in the third photosensitive polymer 251c. The third photosensitive polymer 251c may include, for example, an organic material having a light transmittance such as a silicon resin, epoxy resin, and the like, and include the same or substantially the same material as the first photosensitive polymer 251a and/or the second photosensitive polymer 251b. The third scattering particles 255c may be configured to scatter and emit blue light Lb and may include the same material as the first scattering particles 255a and/or the second scattering particles 255b.

While blue light Lb emitted from the light-emitting panel 10 passes through the first color converting portion 250a, the second color converting portion 250b, and the third color converting portion 250c, the blue light Lb is changed in color or transmitted, and then, color purity thereof may be improved while passing through the filter 240. As an example, blue light Lb emitted from the first display element DPE1 may be converted and filtered as red light Lr while passing through the first color converting portion 250a and the first filter 240a. Blue light Lb emitted from the second display element DPE2 may be converted and filtered as green light Lg while passing through the second color converting portion 250b and the second filter 240b. Blue light Lb emitted from the third display element DPE3 may be transmitted and filtered while passing through the third color converting portion 250c and the third filter 240c.

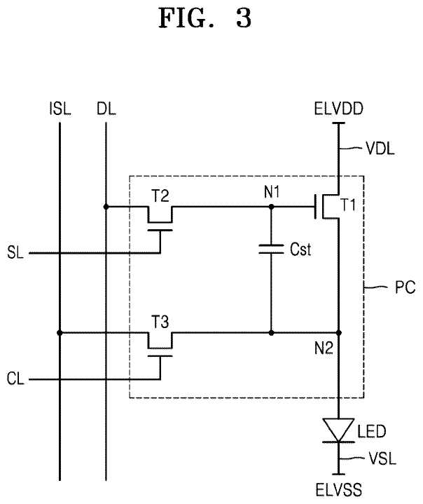

FIG. 3 is a schematic equivalent circuit diagram of a light-emitting diode corresponding to one pixel of the display apparatus and a sub-pixel circuit connected thereto according to some embodiments of the present disclosure.

Referring to FIG. 3, a light-emitting diode, for example, a first electrode (e.g., an anode or a pixel electrode) of a light-emitting diode LED may be connected to a pixel circuit PC, and a second electrode (e.g., a cathode or an opposite electrode) of the light-emitting diode LED may be connected to a common voltage line VSL providing a common voltage ELVSS. The light-emitting diode LED may be configured to emit light at a brightness corresponding to the amount of current supplied from the pixel circuit PC.

The light-emitting diode LED of FIG. 3 may correspond to each of the first to third display elements DPE1, DPE2, and DPE3, and the pixel circuit PC of FIG. 3 may correspond to each of first to third pixel circuits PC1, PC2, and PC3 shown in FIG. 2A.

The pixel circuit PC may be configured to control the amount of current flowing through the light-emitting diode LED in a direction from the driving voltage ELVDD to the common voltage ELVSS in response to a data signal. The pixel circuit PC may include a driving transistor T1, a switching transistor T2, an initialization-sensing transistor T3, and a storage capacitor Cst.

Each of the driving transistor T1, the switching transistor T2, and the initialization-sensing transistor T3 may be an oxide semiconductor thin-film transistor including a semiconductor layer including an oxide semiconductor, or a silicon semiconductor thin-film transistor including a semiconductor layer including polycrystalline silicon. A first electrode may be one of a source electrode and a drain electrode, and a second electrode may be the other of the source electrode and the drain electrode depending on the type of the transistor.

A first electrode of the driving transistor may be connected to a power line VDL configured to supply the driving voltage, and a second electrode may be connected to a first electrode of the light-emitting diode LED. A gate electrode of the driving transistor T1 may be connected to a first node N1. The driving transistor T1 may be configured to control the amount of current flowing through the light-emitting diode LED from the driving voltage ELVDD in response to the voltage of the first node N1.

A first electrode of the switching transistor T2 may be connected to the data line DL, and a second electrode of the switching transistor T2 may be connected to the first node N1. A gate electrode of the switching transistor T2 may be connected to the scan line SL. The switching transistor T2 may be turned on when a scan signal is supplied to the scan line SL and may electrically connect the data line DL to the first node N1.

The initialization-sensing transistor T3 may be an initialization transistor and/or a sensing transistor. A first electrode of the initialization-sensing transistor T3 may be connected to a second node N2, and a second electrode of the initialization-sensing transistor T3 may be connected to an initialization-sensing line ISL. A gate electrode of the initialization-sensing transistor T3 may be connected to a control line CL.

The storage capacitor Cst may be connected between the first node N1 and the second node N2. As an example, a first capacitor electrode of the storage capacitor Cst may be connected to the gate electrode of the driving transistor T1, and a second capacitor electrode of the storage capacitor Cst may be connected to a first electrode of the light-emitting diode LED.

In some embodiments, a method of driving the pixel circuit PC in an image displaying section is as follows.

In a first section during which the switching transistor T2 receives an on-voltage of the scan line SL, the switching transistor T2 is turned on in response to an on-voltage of a scan signal. When the switching transistor T2 is turned on, a data voltage of the data line DL is applied to the gate electrode of the driving transistor T1 connected to the first node N1 and stored in the storage capacitor Cst.

The driving transistor T1 is turned on based on a data voltage, and a driving current flows through the first electrode (e.g., an anode) of the light-emitting diode LED due to the driving voltage ELVDD. The light-emitting diode LED may be configured to emit light and display images using the driving current corresponding to a data voltage.

In a second section during which the sensing transistor T3 receives an on-voltage of the control line CL, the sensing transistor T3 is turned on in response to an on-voltage of a control signal. An initialization voltage of the initialization-sensing line ISL is applied to the second node N2, for example, the first electrode of the light-emitting diode LED. Accordingly, the first electrode of the light-emitting diode LED may be initialized.

A method of driving the pixel circuit PC in a sensing section is as follows.

The switching transistor T2 is turned off in response to an off-voltage of a scan signal, and the sensing transistor T3 is turned off in response to an off-voltage of a control signal. A sensing signal applied to the second node N2 connected to the electrode of the driving transistor T1 and the first electrode of the light-emitting diode LED may be provided to a controller (or a sensing portion) through the initialization-sensing line ISL. The controller may be configured to generate sensing data, which is digital data, using a sensing signal, and to compensate and to correct image data using the sensing data.

Although FIG. 3 shows the driving transistor T1, the switching transistor T2, and the sensing transistor T3 as n-type metal oxide semiconductors (NMOS), embodiments of the present disclosure are not limited thereto. As an example, at least one of the driving transistor T1, the switching transistor T2, and the sensing transistor T3 may be formed as a p-type metal oxide semiconductor (PMOS).

Although FIG. 3 shows three transistors, embodiments of the present disclosure are not limited thereto. For example, the pixel circuit PC may include four or more transistors.

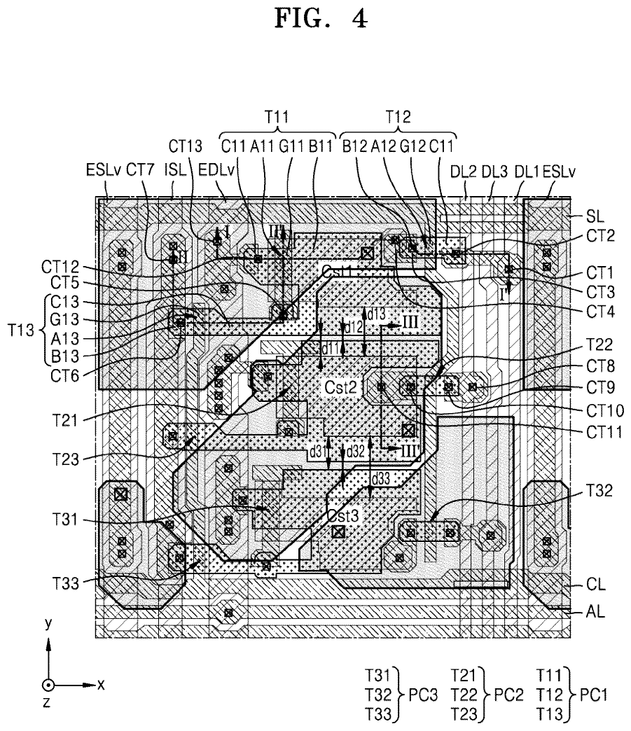

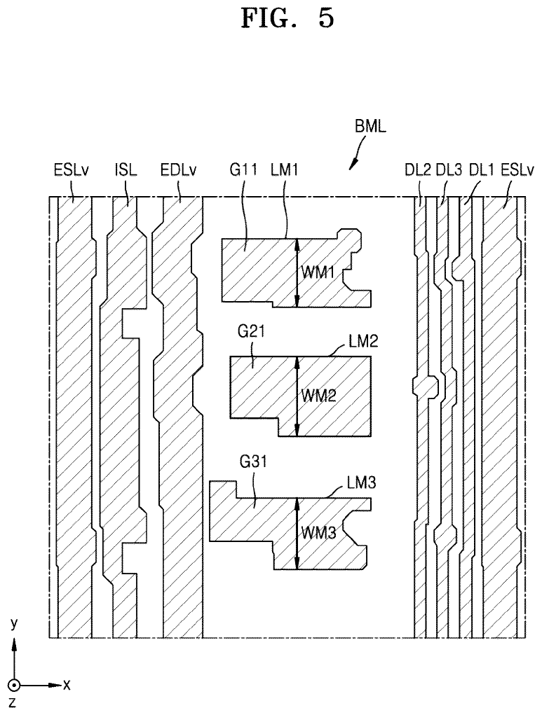

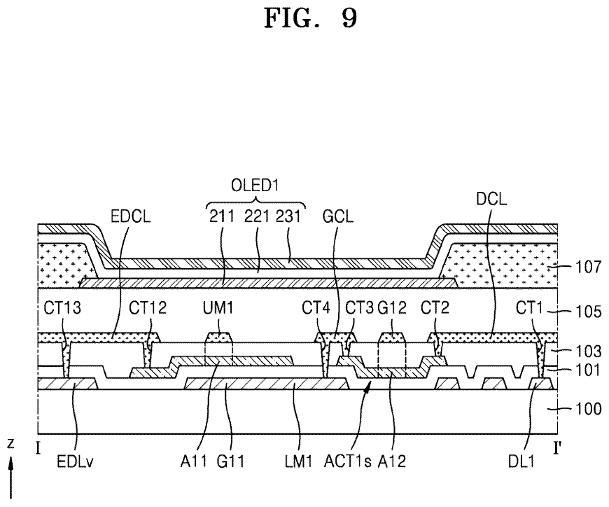

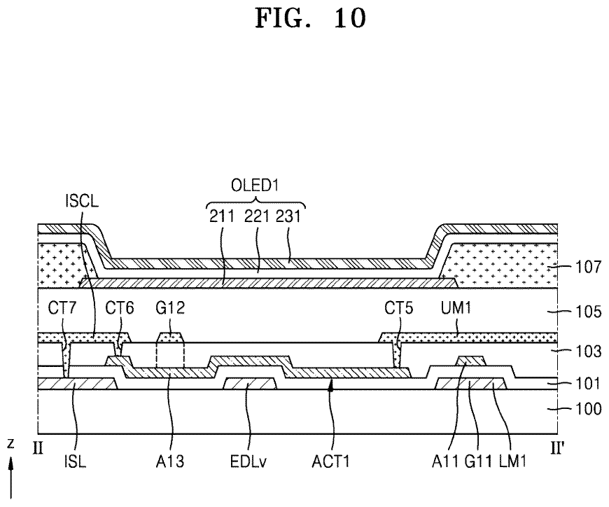

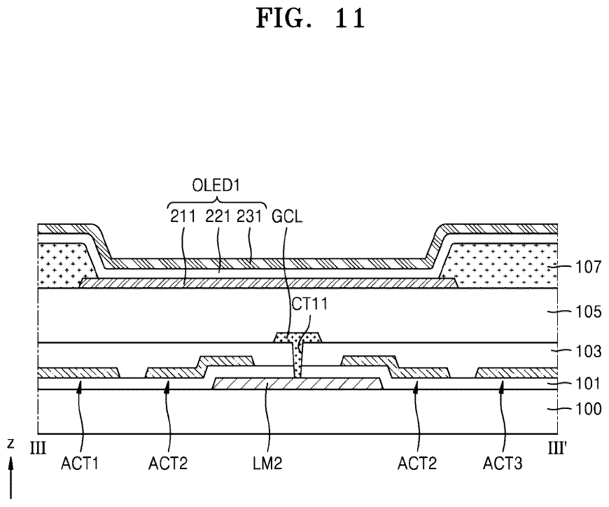

FIG. 4 is a schematic configuration view of the positions of transistors, a storage capacitor, and the like in a pixel of a display apparatus according to some embodiments of the present disclosure. FIGS. 5 to 8 are schematic configuration views of elements such as transistors and a storage capacitor, for each layer, of the display apparatus 1 shown in FIG. 4, according to some embodiments of the present disclosure. FIG. 9 is a schematic cross-sectional view of the display apparatus, taken along the line I-I′ of FIG. 4, according to some embodiments of the present disclosure. FIG. 10 is a schematic cross-sectional view of the display apparatus, taken along the line II-II′ of FIG. 4, according to some embodiments of the present disclosure. FIG. 11 is a schematic cross-sectional view of the display apparatus, taken along the line III-III′ of FIG. 4, according to some embodiments of the present disclosure.

For reference, one pixel may include a plurality of sub-pixels, for example, three sub-pixels. The equivalent circuit diagram of FIG. 3 is an equivalent circuit diagram of one sub-pixel. FIG. 4 schematically shows the positions of transistors, a storage capacitor, and the like in a pixel including three sub-pixels.

Referring to FIGS. 4 to 11, one pixel may include three sub-pixels. That is, one pixel may include a first sub-pixel P1, a second sub-pixel P2, and a third sub-pixel P3. The first sub-pixel P1 is a sub-pixel of a region from which red light is emitted and may be referred to as a red sub-pixel. The second sub-pixel P2 is a sub-pixel of a region from which green light is emitted and may be referred to as a green sub-pixel. The third sub-pixel P3 is a sub-pixel of a region from which blue light is emitted and may be referred to as a blue sub-pixel. Each of the first sub-pixel P1, the second sub-pixel P2, and the third sub-pixel P3 may include one storage capacitor Cst1, Cst2, or Cst3, and three transistors T1, T2, and T3. Elements of the second sub-pixel P2 and the third sub-pixel P3 are the same as or similar to elements of the first sub-pixel P1. Accordingly, hereinafter, for convenience of description, the elements of the first sub-pixel P1 are mainly described. The description is applicable to the elements of the second sub-pixel P2 and the elements of the third sub-pixel P3.

The display apparatus 1 includes a substrate 100 (see, e.g., FIG. 9), and various suitable elements such as transistors T11, T12, and T13, the storage capacitor Cst1 and the like of the first sub-pixel P1 may be disposed on the substrate 100. The substrate 100 may include glass, metal, polymer resin, and/or the like. In the case where the substrate 100 is flexible or bendable, the substrate 100 may include, for example, a polymer resin including polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. The substrate 100 may have a multi-layered structure including two layers each including the polymer resin, and a barrier layer including an inorganic material (such as silicon oxide, silicon nitride, and silicon oxynitride) therebetween. However, various suitable modifications may be made.

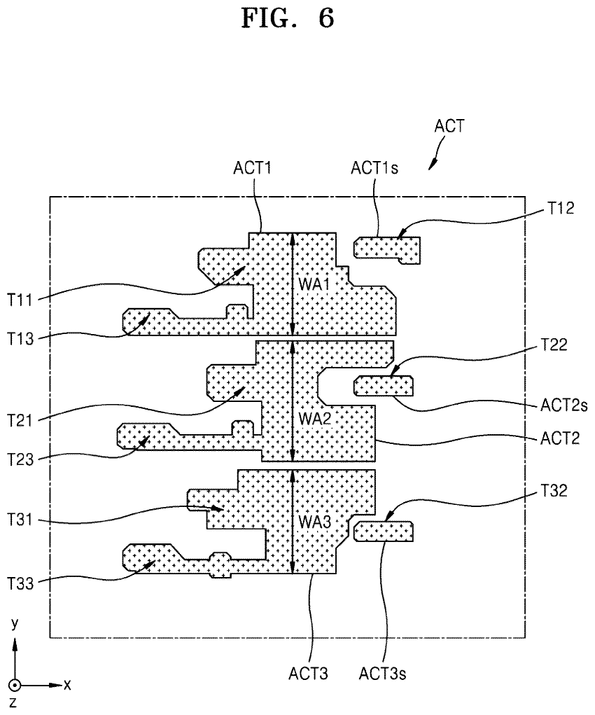

A first buffer layer may be disposed on the substrate 100, which includes an inorganic insulator such as silicon oxide, silicon nitride, silicon oxynitride, or aluminum oxide. The first buffer layer may be configured to prevent metal atoms or impurities and the like from the substrate 100 from diffusing to a semiconductor layer ACT (see, e.g., FIG. 6) disposed thereon, or to substantially reduce such diffusion.

A bottom metal layer (BML) shown in FIG. 5 may be disposed on the substrate 100 or the first buffer layer. The BML may include various suitable signal lines and overlap at least a portion of the semiconductor layer ACT disposed thereon to protect the semiconductor layer ACT (e.g., from external impacts or forces). When the semiconductor layer ACT includes polycrystalline silicon and/or the like, the BML may allow the semiconductor layer ACT to be uniformly crystallized by adjusting a heat providing speed during a crystallization process for forming the semiconductor layer ACT. The BML may include metal, an alloy, a conductive metal oxide, a transparent conductive material, and/or the like. As an example, the BML may include silver (Ag), an alloy containing silver, molybdenum (Mo), an alloy containing molybdenum, aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO) or indium zinc oxide (IZO), and/or the like. The BML may have a multi-layered structure. As an example, the BML may have a two-layered structure of Mo/Al or Ti/Al, or have a three-layered structure of Mo/Al/Mo or Ti/Al/Ti.

As shown in FIG. 5, the BML may include a vertical common voltage line ESLv, an initialization-sensing line ISL, a vertical power line EDLv, a first data line DL1, a second data line DL2, a third data line DL3, first to third lower metals LM1, LM2, and LM3. The vertical common voltage line ESLv, the initialization-sensing line ISL, the vertical power line EDLv, the second data line DL2, the third data line DL3, and the first data line DL1 may be sequentially arranged in a first direction (e.g., an x axis direction).

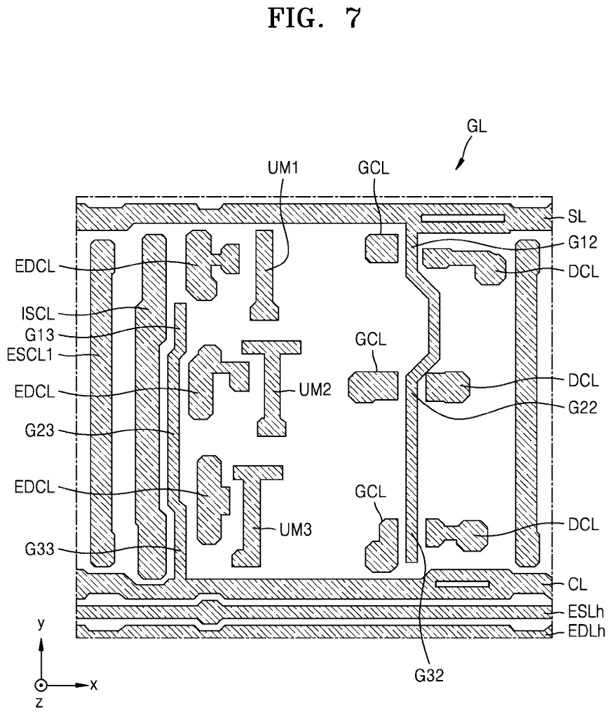

The vertical common voltage line ESLv may extend in a second direction (e.g., a y axis direction) crossing the first direction (e.g., the x axis direction). The vertical common voltage line ESLv may be electrically connected to a horizontal common voltage line ESLh (see, e.g., FIG. 7) extending in the first direction (e.g., the x axis direction). Accordingly, the common voltage line VSL including the vertical common voltage line ESLv and the horizontal common voltage line ESLh electrically connected to each other may have an approximately lattice shape in the display area DA and thus have an approximately uniform electric potential corresponding to the common voltage ELVSS in the display area DA. Because the common voltage line VSL may be electrically connected to an opposite electrode 231 (see, e.g., FIG. 9), which is an upper electrode of the organic light-emitting diode, the opposite electrode 231 may have a uniform (e.g., the same or substantially the same) electric potential in the display area DA.

The initialization-sensing line ISL may extend in the second direction (e.g., the y axis direction). The initialization-sensing line ISL may be electrically connected to each of third transistors T13, T23, and T33, which are initialization-sensing transistors, and, when the third transistors T13, T23, and T33 are turned on, the initialization-sensing line ISL may allow an initialization-sensing signal from the initialization-sensing line ISL to be transferred to a first pixel electrode 211-1, a second pixel electrode 211-2, or a third pixel electrode 211-3.

The vertical power line EDLv may extend in the second direction (e.g., the y axis direction) crossing the first direction (the x axis direction). The vertical power line EDLv may be electrically connected to a horizontal power line EDLh (see, e.g., FIG. 7) extending in the first direction (e.g., the x axis direction). Accordingly, the power line VDL including the vertical power line EDLv and a horizontal power line EDLh electrically connected to each other may have an approximately lattice shape in the display area DA and thus have an approximately uniform electric potential corresponding to the driving voltage ELVDD in the display area DA. The power line VDL may be electrically connected to each of first transistors T11, T21, and T31, which are driving transistors, to apply the driving voltage ELVDD to the first transistors T11, T21, and T31.

Each of the second data line DL2, the third data line DL3, and the first data line DL1 may extend in the second direction (e.g., the y axis direction). The first data line DL1 is a red data line and electrically connected to the second transistor T12 of the first sub-pixel, the second data line DL2 is a green data line and electrically connected to the second transistor T22 of the second sub-pixel, and the third data line DL3 is a blue data line and electrically connected to the second transistor T32 of the third sub-pixel. When the second transistor T12 of the first sub-pixel, the second transistor T22 of the second sub-pixel, and the second transistor T32 of the third sub-pixel are turned on by the scan line SL (see, e.g., FIG. 7), the second transistor T12 of the first sub-pixel, the second transistor T22 of the second sub-pixel, and the second transistor T32 of the third sub-pixel may be configured to transfer data signals from the first data line DL1, the second data line DL2, and the third data line DL3 to a driving gate electrode G11 of the first transistor T11 of the first sub-pixel, a driving gate electrode G21 of the first transistor T21 of the second sub-pixel, and a driving gate electrode G31 of the first transistor T31 of the third sub-pixel.

The first lower metal LM1, the second lower metal LM2, and the third lower metal LM3 may be arranged between a set of the vertical common voltage line ESLv, the initialization-sensing line ISL, and the vertical power line PLv, and a set of the second data line DL2, the third data line DL3, and the first data line DL1. The first lower metal LM1, the second lower metal LM2, and the third lower metal LM3 may be arranged side-by-side in the second direction (e.g., the y axis direction). When viewed in a direction (e.g., a z axis direction) perpendicular to the substrate 100 (that is, in a plan view), the first lower metal LM1, the second lower metal LM2, and the third lower metal LM3 may each have an isolated shape.

The first lower metal LM1, the second lower metal LM2, and the third lower metal LM3 may each be the first capacitor electrode of the storage capacitor Cst. The first lower metal LM1, the second lower metal LM2, and the third lower metal LM3 may be a driving gate electrode G11 of the first transistor T11 of the first sub-pixel, a driving gate electrode G21 of the first transistor T21 of the second sub-pixel, and a driving gate electrode G31 of the first transistor T31 of the third sub-pixel, respectively.

A second buffer layer 101 (see, e.g., FIG. 9) may be disposed over the substrate 100 or the first buffer layer to cover the BML. The second buffer layer 101 may include an insulating material. As an example, the second buffer layer 101 may include an inorganic insulating material such as silicon oxide, silicon nitride, silicon oxynitride, or aluminum oxide.

The semiconductor layer ACT shown in FIG. 6 may be disposed on the second buffer layer 102. The semiconductor layer ACT may include polycrystalline silicon or an oxide semiconductor. An oxide semiconductor is a Zn oxide-based material and may include Zn oxide, In—Zn oxide, Ga—In—Zn oxide, and/or the like. In some examples, the oxide semiconductor may include In—Ga—Zn—O (IGZO), In—Sn—Zn—O (ITZO), In—Ga—Sn—Zn—O (IGTZO), and/or the like containing metal such as indium (In), gallium (Ga), and stannum (Sn) in ZnO. Hereinafter, for convenience, the case where the semiconductor layer ACT includes an oxide semiconductor is described.

The semiconductor layer ACT may include a first semiconductor layer ACT1, a second semiconductor layer ACT2, a third semiconductor ACT3, a first sub-semiconductor layer ACT1s, a second sub-semiconductor layer ACT2s, and a third sub-semiconductor layer ACT3s. The semiconductor layer ACT of the first sub-pixel P1 is mainly described. The first semiconductor layer ACT1 may be an element of the first transistor T11 and the third transistor T13. The first transistor T11 may be the driving transistor, and the third transistor T13 may be the initialization-sensing transistor.

The first semiconductor layer ACT1 may overlap the first lower metal LM1 corresponding to the first capacitor electrode of the storage capacitor Cst1 to serve as the second capacitor electrode. The first sub-semiconductor layer ACT1s may be an element of the second transistor T12. The second transistor T12 may be the switching transistor. Although the first semiconductor layer ACT1 and the first sub-semiconductor layer ACT1s may be separately formed, embodiments of the present disclosure are not limited thereto. In some embodiments, the first semiconductor layer ACT1 and the first sub-semiconductor layer ACT1s are integrally formed (e.g., formed as a unitary body).

Likewise, the second sub-pixel P2 may include the second semiconductor layer ACT2 and the second sub-semiconductor layer ACT2s, and the third sub-pixel P3 may include the third semiconductor layer ACT3 and the third sub-semiconductor layer ACT3s.

A gate insulating layer 103 (see, e.g., FIG. 9) may be disposed on the second buffer layer 101 to cover the semiconductor layer ACT. The gate insulating layer 103 may include an insulating material. As an example, the gate insulating layer 103 may include an inorganic insulating material such as silicon oxide, silicon nitride, silicon oxynitride, or aluminum oxide.

As shown in FIG. 7, a gate layer GL may be disposed on the gate insulating layer 103.

The gate layer GL may include the horizontal common voltage line ESLh, the scan line SL, the control line CL, and the horizontal power line EDLh extending in the first direction (e.g., the x axis direction). The gate line GL may include a first common voltage connection line ESCL1 and an initialization-sensing connection line ISCL extending in the approximately second direction (e.g., the y axis direction). The gate line GL may include first to third upper metals UM1, UM2, and UM3, a gate connection line GCL, a data connection line DCL, and a power connection line EDCL. The gate line GL may include switching gate electrodes G12, G22, and G32 and initialization-sensing gate electrodes G13, G23, and G33.

In some embodiments, the first sub-pixel P1, the second sub-pixel P2, and the third sub-pixel P3 each includes the power connection line EDCL and one of the data connection line DCL, the gate connection line GCL, and the first to third upper metals UM1, UM2, and UM3. The first upper metal UM1, the second upper metal UM2, and the third upper metal UM3 may be arranged side-by-side in the second direction (e.g. the y axis direction). The first upper metal UM1, the second upper metal UM2, and the third upper metal UM3 may each extend in the second direction (e.g., the y axis direction). The first upper metal UM1, the second upper metal UM2, and the third upper metal UM3 may each be arranged between the power connection line EDCL and the gate connection line GCL in a plan view.

The gate layer GL may include metal, an alloy, a conductive metal oxide, a transparent conductive material, and/or the like. As an example, the gate layer GL may include silver (Ag), an alloy containing silver, molybdenum (Mo), an alloy containing molybdenum, aluminum (AI), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO) or indium zinc oxide (IZO), and/or the like. The gate layer GL may have a multi-layered structure. As an example, the gate layer GL may have a two-layered structure of Mo/Al or Ti/Al, or have a three-layered structure of Mo/Al/Mo or Ti/Al/Ti.

A portion of the gate line GL not overlapping the semiconductor layer ACT may be doped with impurities. That is, a portion of the semiconductor layer ACT not overlapping the gate layer GL may be a doped portion. Accordingly, the electrical characteristics of a portion of the semiconductor layer ACT not overlapping the gate layer GL may be different from the electrical characteristics of a portion of the semiconductor layer ACT overlapping the gate layer GL. For example, a resistance of a portion of the semiconductor layer ACT not overlapping the gate layer GL may be less than a resistance of a portion of the semiconductor layer ACT overlapping the gate layer GL when no channel is formed in the portion of the semiconductor layer ACT overlapping the gate layer GL. Accordingly, in the first sub-pixel P1, a portion of the first semiconductor layer ACT1 overlapping the first lower metal LM1 including the first capacitor electrode may serve as a conductor and as the second capacitor electrode. In addition, a portion of the semiconductor layer ACT not overlapping the gate layer GL may be a source region or a drain region and may simultaneously serve as a wiring.

The first sub-pixel P1 is described as an example. The first transistor T11 may include the driving gate electrode G11 and the first semiconductor layer ACT1. Similarly, the second transistor T12 may include the switching gate electrode G12 and the first sub-semiconductor layer ACT1s. The third transistor T13 may include the initialization-sensing gate electrode G13 and the first semiconductor layer ACT1. A portion of the first semiconductor layer ACT1 and a portion of the first sub-semiconductor layer ACT1s may overlap the driving gate electrode G11, the switching gate electrode G12, and the initialization-sensing gate electrode G13, and respective portions of the semiconductor layer ACT may be defined as a channel portion. A portion of the first semiconductor layer ACT1 and a portion of the first sub-semiconductor layer ACT1s may each include a first portion and a second portion with the channel portion therebetween.

The gate line GL includes a contact hole and may be electrically connected to a portion of the semiconductor layer ACT and/or the BML. The contact hole of the gate layer GL is shown in FIG. 4 in a plan view. For simplification of the drawing, the illustration of the contact hole is omitted in FIG. 7. The contact hole of the gate layer GL is described with reference to FIGS. 9 to 11 together. Description of the first sub-pixel P1 is equally applicable to the second sub-pixel P2 and the third sub-pixel P3.

The first sub-pixel P1 is mainly described with reference to FIG. 9. The data connection line DCL may be electrically connected to the first data line DL1 in the lower portion through a first contact hole CT1 and electrically connected to the first sub-semiconductor layer ACT1s in the lower portion through a second contact hole CT2. The gate connection line GCL may be electrically connected to the first sub-semiconductor layer ACT1s in the lower portion through a third contact hole CT3 and electrically connected to the first lower metal LM1 through a fourth contact hole CT4. The power connection line EDCL may be electrically connected to the first semiconductor layer ACT1 through a 12-th contact hole CT12 and electrically connected to the vertical power line EDLv through a 13-th contact hole CT13.

The first sub-pixel P1 is mainly described with reference to FIG. 10. The first upper metal UM1 may be electrically connected to the first semiconductor layer ACT1 through a fifth contact hole CT5. The initialization-sensing line ISCL may be electrically connected to the first semiconductor layer ACT1 through a sixth contact hole CT6 and electrically connected to the initialization-sensing line ISL through a seventh contact hole CT7.

The second sub-pixel P2 is mainly described with reference to FIG. 11. The data connection line DCL may be electrically connected to the second data line DL2 through an eighth contact hole CT8 and electrically connected to the second sub-semiconductor layer ACT2s through a ninth contact hole CT9. The gate connection line GCL may be electrically connected to the second sub-semiconductor layer ACT2s through a tenth contact hole CT10 and electrically connected to the second lower metal LM2 through an eleventh contact hole CT11.

A planarization layer 105 may cover the gate line GL and be disposed on the gate line GL. The planarization layer 105 may include an organic insulating material. As an example, the planarization layer 105 may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof.

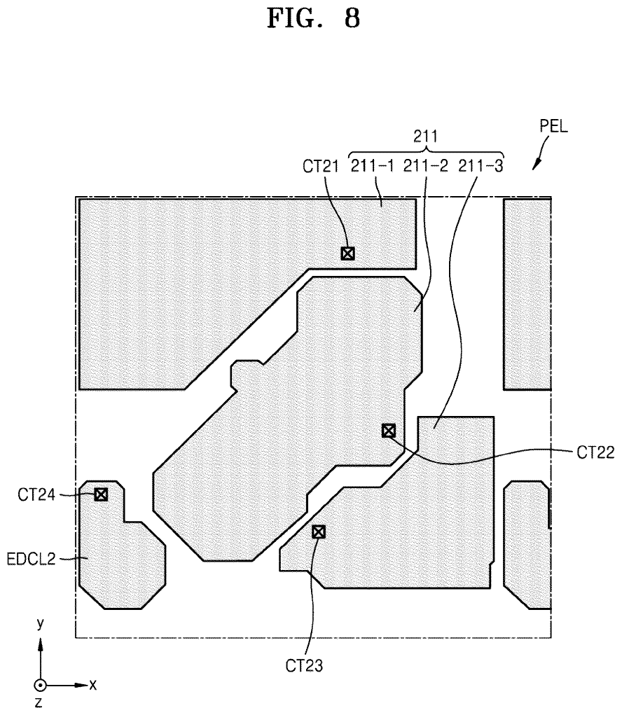

A pixel electrode layer PEL shown in FIG. 8 may be disposed on the planarization layer 105. The pixel electrode layer PEL may include a first pixel electrode 211-1, a second pixel electrode 211-2, a third pixel electrode 211-3, and a second common voltage connection line EDCL2. The pixel electrode layer PEL may be a (semi) light-transmissive electrode layer or a reflective electrode layer. As an example, the pixel electrode layer PEL may include a reflective layer and a transparent or semi-transparent electrode layer on the reflective layer, which includes Ag, Mg, Al, Pt, Pd, Au, Ni, Nd, Ir, Cr, or a compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO). As an example, the pixel electrode layer PEL may have a three-layered structure of ITO/Ag/ITO.

The first pixel electrode 211-1 is a pixel electrode in a region from which red light is emitted and may be referred to as a red pixel electrode. The second pixel electrode 211-2 is a pixel electrode in a region from which green light is emitted and may be referred to as a green pixel electrode. The third pixel electrode 211-3 is a pixel electrode in a region from which blue light is emitted and may be referred to as a blue pixel electrode.

The first pixel electrode 211-1 may be connected to the first sub-pixel electrode P1 and, for example, electrically connected to the first semiconductor layer ACT1 of the first sub-pixel P1 in the lower portion through a 21-st contact hole CT21. The second pixel electrode 211-2 may be connected to the second sub-pixel electrode P2 and, for example, electrically connected to the second semiconductor layer ACT2 of the second sub-pixel P2 through a 22-nd contact hole CT22. The third pixel electrode 211-3 may be connected to the third sub-pixel electrode P3 and, for example, electrically connected to the third semiconductor layer ACT3 of the third sub-pixel P3 in the lower portion through a 23-rd contact hole CT23.

A pixel-defining layer 107 may be disposed on the planarization layer 105. The pixel-defining layer 107 has openings to expose the central portion of each of the first pixel electrode 211-1, the second pixel electrode 211-2, and the third pixel electrode 211-3 and may cover the edges of each of the first pixel electrode 211-1, the second pixel electrode 211-2, and the third pixel electrode 211-3. Accordingly, the pixel-defining layer 107 may prevent or substantially reduce arcs and the like from occurring at the edges of the first pixel electrode 211-1, the second pixel electrode 211-2, and the third pixel electrode 211-3 by increasing a distance between the opposite electrode 231 and the edges of each of the first pixel electrode 211-1, the second pixel electrode 211-2, and the third pixel electrode 211-3. In addition, the pixel-defining layer 107 may allow the opposite electrode 231 to be in contact with the second common voltage connection line ESCL2 by exposing at least a portion of the second common voltage connection line ESCL2. Because the second common voltage connection line ESCL2 is electrically connected to the first common voltage connection line ESCL1 in the lower portion through a 24-th contact hole CT24, the opposite electrode 231 may be electrically connected to the common voltage line VSL including the vertical common voltage line ESLv and the horizontal common voltage line ESLh through the second common voltage connection line ESCL2 and the first common voltage connection line ESCL1. The pixel-defining layer 107 may include an organic insulating material such as polyimide, an acrylic resin, benzocyclobutene, a phenolic resin, and/or the like and be formed by using spin coating and/or the like.

The opposite electrode 231 may be a light-transmissive electrode or a reflective electrode. As an example, the opposite electrode 231 may be a transparent or semi-transparent electrode and may include a metal thin film including Li, Ca, LiF, Al, Ag, Mg, or compound thereof and having a small work function. In addition, the opposite electrode 231 may further include a transparent conductive oxide (TCO) layer such as ITO, indium zinc oxide (IZO), ZnO, or In₂O₃ disposed on the metal thin film. The opposite electrode 231 may be integrally formed (e.g., formed as a unitary body) over the entire surface of the display area DA and disposed over a plurality of pixel electrodes.

An intermediate layer may be disposed between the pixel electrodes 211 and the opposite electrode 231. At least a portion of the intermediate layer may be disposed in the opening formed by the pixel-defining layer 107. A light-emitting area of an organic light-emitting diode OLED may be defined by the opening. The intermediate layer may include an emission layer. The emission layer may include an organic material including a fluorescent or phosphorous material configured to emit red, green, blue, or white light. The emission layer may include a polymer organic material or a low molecular weight organic material. Functional layers may be selectively further arranged under and on the emission layer, the functional layers including a hole transport layer (HTL), a hole injection layer (HIL), an electron transport layer (ETL), and an electron injection layer (EIL).

The emission layer may have a shape patterned to correspond to each of the pixel electrodes. Layers of the intermediate layer other than the emission layer may be integrated over the plurality of pixel electrodes. However, various suitable modifications may be made.

Referring to FIGS. 4 to 7, the display apparatus 1 according to some embodiments includes the first sub-pixel P1, the second sub-pixel P2, and the third sub-pixel P3, each of which is configured to display light of different colors. The first sub-pixel P1 may include the first lower metal LM1, the first semiconductor layer ACT1, and the first upper metal UM1, the second sub-pixel P2 may include the second lower metal LM2, the second semiconductor layer ACT2, and the second upper metal UM2, and the third sub-pixel P3 may include the third lower metal LM3, the third semiconductor layer ACT3, and the third upper metal UM3.

In some embodiments, the first lower metal LM1, the second lower metal LM2, and the third lower metal LM3 are arranged in the second direction (e.g., the y axis direction). The first semiconductor layer ACT1, the second semiconductor layer ACT2, and the third semiconductor layer ACT3 may each overlap the first lower metal LM1, the second lower metal LM2, and the third lower metal LM3 and be arranged in the second direction (e.g., the y axis direction).

In some embodiments, an interval d11 between the second lower metal LM2 and the first semiconductor layer ACT1 is greater than an interval d12 between the second semiconductor layer ACT2 and the first semiconductor layer ACT1. The interval d11 between the second lower metal LM2 and the first semiconductor layer ACT1 may be less than an interval d13 between the second lower metal LM2 and the first lower metal LM1. In other words, the second lower metal LM2 of the second sub-pixel P2 may be covered by the second semiconductor layer ACT2 and may not be exposed in the direction toward the adjacent first sub-pixel P1. Likewise, the first lower metal LM1 of the first sub-pixel P1 may be covered by the first semiconductor layer ACT1 and may not be exposed in the direction toward the adjacent second sub-pixel P2.

In some embodiments, an interval d31 between the second lower metal LM2 and the third semiconductor layer ACT3 is greater than an interval d32 between the second semiconductor layer ACT2 and the third semiconductor layer ACT3. The interval d31 between the second lower metal LM2 and the third semiconductor layer ACT3 may be less than an interval between the second lower metal LM2 and the third lower metal LM3. In other words, the second lower metal LM2 of the second sub-pixel P2 may be covered by the second semiconductor layer ACT2 and may not be exposed in the direction toward the adjacent third sub-pixel P3. Likewise, the third lower metal LM3 of the third sub-pixel P3 may be covered by the third semiconductor layer ACT3 and may not be exposed in the direction toward the adjacent second sub-pixel P2.

The interval denotes an interval between sides adjacent to each other in a plan view. In the case where the first to third lower metals LM1, LM2, and LM3 and the first to third semiconductor layers ACT1, ACT2, and ACT3 are arranged in the second direction (e.g., the y axis direction), it may denote an interval between adjacent sides in the second direction (e.g., the y axis direction).

In some embodiments, a width WM1 of the first lower metal LM1 is less than a width WA1 of the first semiconductor layer ACT1. A width WM2 of the second lower metal LM2 may be less than a width WA2 of the second semiconductor layer ACT2. A width WM3 of the third lower metal LM3 may be less than a width WA3 of the third semiconductor layer ACT3. The width may denote a width in a direction in which the adjacent sub-pixels are arranged in a plan view. As an example, in the case of FIG. 4, the width may denote a width in the second direction (e.g., the y axis direction).

In some embodiments, the first lower metal LM1 includes the driving gate electrode G11 of the first transistor T11 of the first sub-pixel P1, the second lower metal LM2 includes the driving gate electrode G21 of the first transistor T21 of the second sub-pixel P2, and the third lower metal LM3 includes the first transistor T31 of the third sub-pixel P3. The first semiconductor layer ACT1 may be electrically connected to the first pixel electrode 211-1, the second semiconductor layer ACT2 may be electrically connected to the second pixel electrode 211-2, and the third semiconductor layer ACT3 may be electrically connected to the third pixel electrode 211-3.

A coupling gap between a gate electric potential of the driving transistor of one sub-pixel and an electric potential of a pixel electrode of a sub-pixel adjacent thereto may generate a color step difference. As an example, a color step difference, noise, or energy loss and the like may occur due to coupling between the second lower metal LM2 of the second sub-pixel P2 to which a gate electric potential of the driving transistor is applied, and the first semiconductor layer ACT1 of the first sub-pixel P1 to which an electric potential of the first pixel electrode 211-1 is applied.

According to some embodiments, because each of the first lower metal LM1, the second lower metal LM2, and the third lower metal LM3 to each of which a gate electric potential of the driving transistor is applied has a configuration relationship with the first semiconductor layer ACT1, the second semiconductor layer ACT2, and the third semiconductor layer ACT3, a color step difference and the like due to coupling are prevented or reduced.

For example, because the first lower metal LM1 is covered by the first semiconductor layer ACT1, coupling (e.g., electrical coupling) that may occur between the first lower metal LM1 and the second semiconductor layer ACT2 may be reduced. Because the second lower metal LM2 is covered by the second semiconductor layer ACT2, coupling (e.g., electrical coupling) that may occur between the second lower metal LM2 and the first semiconductor layer ACT1 or between the second lower metal LM2 and the third semiconductor layer ACT3 may be reduced. Because the third lower metal LM3 is covered by the third semiconductor layer ACT3, coupling (e.g., electrical coupling) that may occur between the third lower metal LM3 and the second semiconductor layer ACT2 may be reduced.

A portion of a region in which the gate connection line GCL of the second sub-pixel P2 is arranged may be a region in which the second semiconductor layer ACT2 is apart from the second sub-semiconductor layer ACT2s and thus the second lower metal LM2 is not covered by the second semiconductor layer ACT2. As described above, in the case where the second lower metal LM2 is exposed, coupling (e.g., electrical coupling) may occur in relation with the adjacent sub-pixels.

According to some embodiments, the gate connection line GCL included in the second sub-pixel P2 is surrounded by the second semiconductor layer ACT2. In a plan view, three or more sides of the gate connection line GCL may be surrounded by the second semiconductor layer ACT2. In the second sub-pixel P2, the second semiconductor layer ACT2 may be arranged between the gate connection line GCL and the first semiconductor layer ACT1 and between the gate connection line GCL and the third semiconductor layer ACT3 in a plan view. Accordingly, coupling between the second lower metal LM2 and the first semiconductor layer ACT1 and between the second lower metal LM2 and the third semiconductor layer ACT3 may be prevented or reduced. In the case where four or more sub-pixels are arranged in one pixel in the second direction (e.g., the y axis direction), the above effect is equally applicable to the rest of sub-pixels except two sub-pixels in the outermost portion in the second direction.

In some embodiments, the first upper metal UM1, the second upper metal UM2, and the third upper metal UM3 each extend in the second direction (e.g., the y axis direction). One end of at least one of the first upper metal UM1, the second upper metal UM2, and the third upper metal UM3 may extend in the first direction (e.g., the x axis direction). At least one of the first upper metal UM1, the second upper metal UM2, and the third upper metal UM3 having one end extending in the first direction (e.g., the x axis direction) may have an approximately T shape or inverted T shape. One end extending in the first direction (e.g., the x axis direction) may be a portion adjacent to another sub-pixel.

As an example, as shown in FIGS. 4-7, with the second upper metal UM2 of the second sub-pixel extended in the second direction (e.g., the y axis direction), one end of the second upper metal UM2 adjacent to the first sub-pixel P1 may have a T shape (e.g., a cross-bar shape) extending in the first direction (e.g., the x axis direction). In this case, a portion of the second lower metal LM2 not covered by the second semiconductor layer ACT2 may be covered. With the third upper metal UM3 of the third sub-pixel extended in the second direction (e.g., the y axis direction), one end of the third upper metal UM3 adjacent to the second sub-pixel P2 may have a T shape (e.g., a cross-bar shape) extending in the first direction (e.g., the x axis direction). In this case, a portion of the third lower metal LM3 not covered by the third semiconductor layer ACT3 may be covered. Accordingly, coupling occurring between adjacent metals may be prevented or substantially reduced.

Because the first lower metal LM1, the second lower metal LM2, and the third lower metal LM3 each have the above-describe configuration in relation with the first semiconductor layer ACT1, the second semiconductor layer ACT2, and the third semiconductor layer ACT3, the first lower metal LM1, the second lower metal LM2, and the third lower metal LM3 may each be arranged to overlap a pixel electrode of another adjacent sub-pixel. Accordingly, some embodiments of the present disclosure provide a display apparatus having a high degree of freedom in the configuration of the pixel electrode, that is, a high degree of freedom in the configuration of an emission area.

In some embodiments, the first pixel electrode 211-1, the second pixel electrode 211-2, and the third pixel electrode 211-3 are diagonally arranged side-by-side in a plan view. In other words, the first pixel electrode 211-1, the second pixel electrode 211-2, and the third pixel electrode 211-3 may be arranged side-by-side in a third direction crossing the first direction (e.g., the x axis direction) and the second direction (e.g., the y axis direction). As an example, the first pixel electrode 211-1, the second pixel electrode 211-2, and the third pixel electrode 211-3 may be arranged side-by-side in a direction crossing both the horizontal power line EDLh extending in the first direction, and the vertical power line EDLv extending in the second direction in a plan view. In addition, the first pixel electrode 211-1, the second pixel electrode 211-2, and the third pixel electrode 211-3 may be arranged side-by-side in a direction crossing both the horizontal common voltage line ESLh extending in the first direction, and the vertical common voltage line ESLv extending in the second direction in a plan view.

In some embodiments, the first pixel electrode 211-1 is arranged to overlap a portion of the scan line SL in a plan view. In addition, the first pixel electrode 211-1 may be arranged to overlap a portion of the common voltage line ESLv, the initialization-sensing line ISL, and the vertical power line EDLv. Accordingly, the first pixel electrode 211-1 may have an approximate triangular shape having one side extending in the first direction and one side extending in the second direction.

In some embodiments, the second pixel electrode 211-2 in the center partially overlaps the first sub-pixel P1 in a plan view. For example, the second pixel electrode 211-2 may partially overlap the first lower metal LM1 of the first sub-pixel P1 in a plan view. In addition, the second pixel electrode 211-2 may partially overlap the first semiconductor layer ACT1 of the first sub-pixel P1 in a plan view. That is, the second pixel electrode 211-2 may overlap a portion of the storage capacitor Cst of the first sub-pixel P1.

In addition, the second pixel electrode 211-2 may partially overlap the third sub-pixel P3 in a plan view. For example, the second pixel electrode 211-2 may partially overlap the first semiconductor layer ACT1 of the third sub-pixel P3 in a plan view. Accordingly, the second pixel electrode 211-2 may have a shape extending from an upper right corner to a lower left corner in a plan view. In this case, the upper right corner of the second pixel electrode 211-2 may overlap the first sub-pixel P1. The lower left corner of the second pixel electrode 211-2 may overlap the third sub-pixel P3.

As described above, the second pixel electrode 211-2 in the center may be arranged to overlap a portion of the first sub-pixel P1 and/or the second sub-pixel P2. In this case, the first pixel electrode 211-1 and the third pixel electrode 211-3 may be arranged not to overlap the second sub-pixel P2.

The third pixel electrode 211-3 may be arranged to overlap a portion of the control line CL in a plan view. In addition, the third pixel electrode 211-3 may be arranged to overlap a portion of the data lines DL1, DL2, and DL3 in a plan view. Accordingly, the third pixel electrode 211-3 may have an approximate triangular shape having one side extending in the first direction and one side extending in the second direction. In addition, because the third pixel electrode 211-3 is a blue pixel electrode and has a brightness less than red or green, even though the third pixel electrode 211-3 overlaps a portion of the data lines DL1, DL2, and DL3, a vertical crosstalk phenomenon due to electric interference between data voltages may not occur.

In addition, in some embodiments, each of the first pixel electrode 211-1, the second pixel electrode 211-2, and the third pixel electrode 211-3 is arranged not to overlap a transistor of another adjacent sub-pixel.

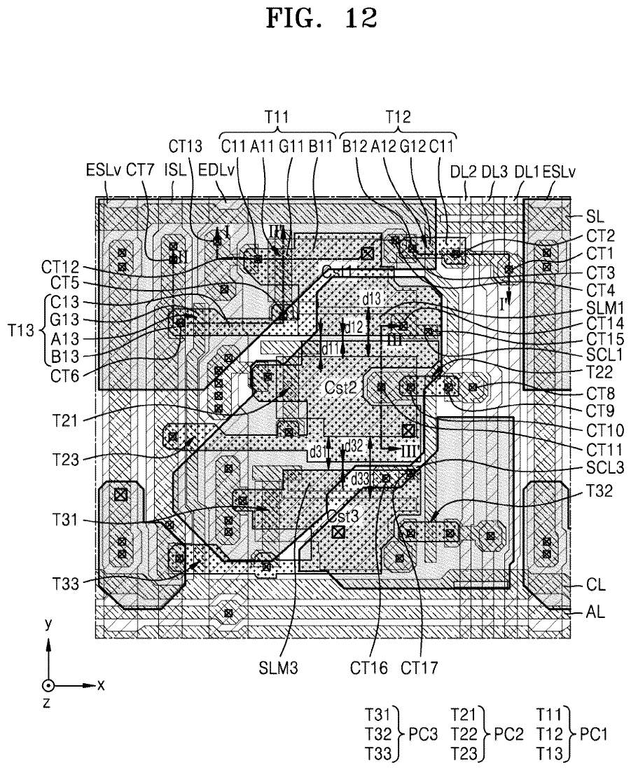

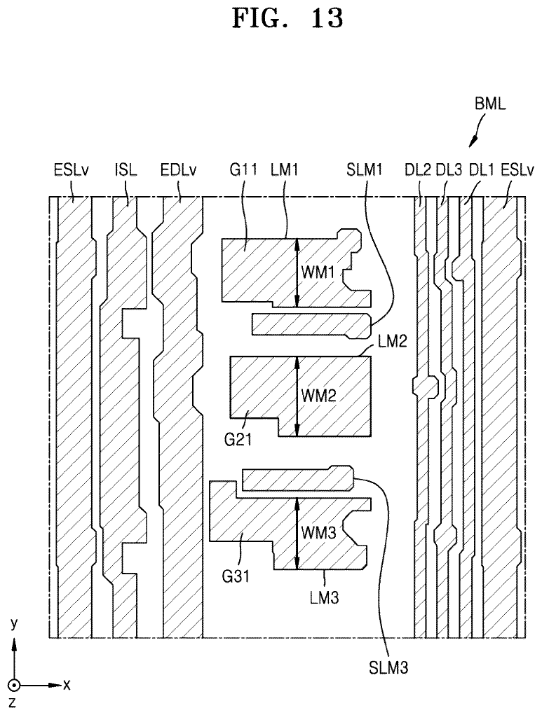

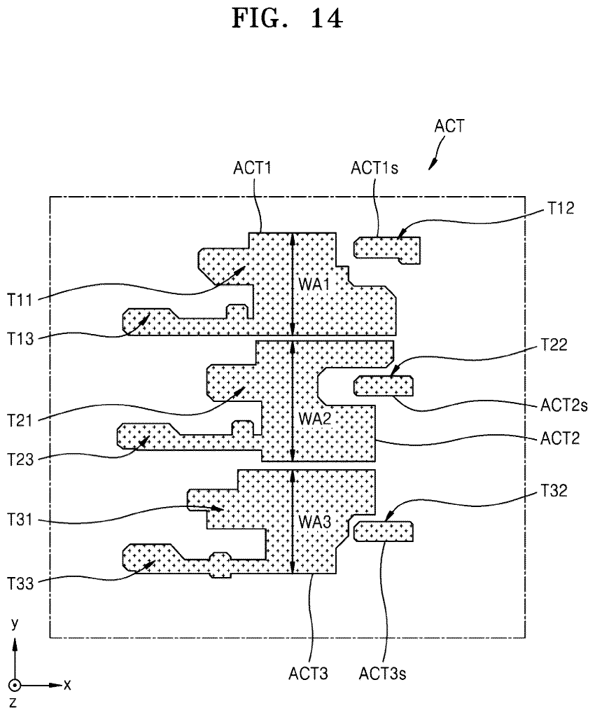

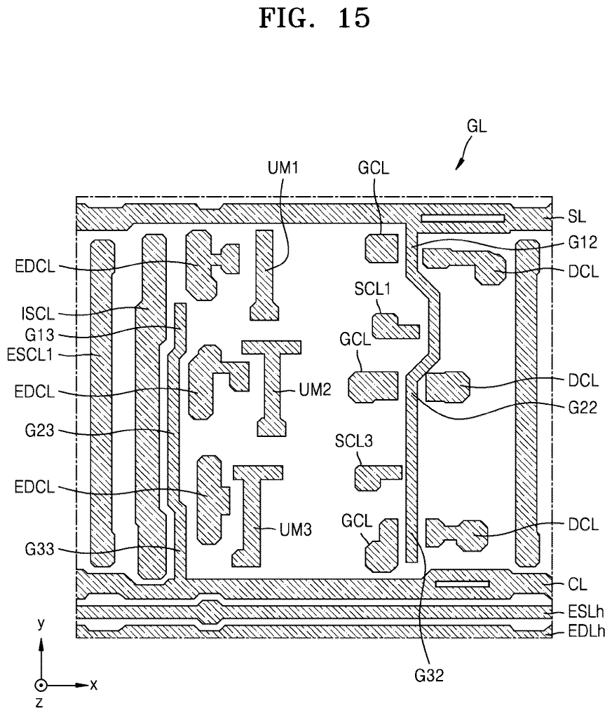

FIG. 12 is a schematic configuration view of the positions of transistors, a storage capacitor, and the like in a pixel of a display apparatus according to some embodiments of the present disclosure. FIGS. 13 to 15 are schematic configuration views of elements such as transistors and a storage capacitor, for each layer, of the display apparatus shown in FIG. 12, according to some embodiments of the present disclosure. Reference numerals repeated in FIGS. 4 to 8 denote the same elements, and thus, repeated descriptions thereof are omitted for purposes of brevity, and differences from FIGS. 4 to 8 are mainly described.

Referring to FIGS. 12 to 15, the BML may further include a first sub-lower metal SLM1 and a third sub-lower metal SLM3. The first sub-lower metal SLM1 may be arranged between the first lower metal LM1 and the second lower metal LM2. The third sub-lower metal SLM3 may be arranged between the third lower metal LM3 and the second lower metal LM2.

The gate layer GL may further include a first sub-connection line SCL1 and a third sub-connection line SCL3. The first sub-connection line SCL1 may at least partially overlap the first sub-lower metal SLM1 and the first semiconductor layer ACT1, and the third sub-connection line SCL3 may at least partially overlap the third sub-lower metal SLM3 and the third semiconductor layer ACT3.

The first sub-connection line SCL1 may be electrically connected to the first sub-lower metal SLM1 through a 14-th contact hole CT14, and electrically connected to the first semiconductor layer ACT1 through a 15-th contact hole CT15. The third sub-connection line SCL3 may be electrically connected to the third sub-lower metal SLM3 through a 16-th contact hole CT16, and electrically connected to the third semiconductor layer ACT3 through a 17-th contact hole CT17.

As described above, because the first semiconductor layer ACT1 is electrically connected to the first pixel electrode 211-1, and the third semiconductor layer ACT3 is electrically connected to the third pixel electrode 211-3, an electric potential of the first pixel electrode 211-1 may be applied to the first sub-lower metal SLM1, and an electric potential of the third pixel electrode 211-3 may be applied to the third sub-lower metal SLM3.

According to some embodiments, the first sub-lower metal SLM1 to which an electric potential of the first pixel electrode 211-1 is applied is disposed between the first lower metal LM1 and the second semiconductor layer ACT2 to which an electric potential of the driving gate is applied. The third sub-lower metal SLM3 to which an electric potential of the third pixel electrode 211-3 is applied may be disposed between the third lower metal LM3 and the second semiconductor layer ACT2 to which an electric potential of the driving gate is applied. Accordingly, coupling between the first lower metal LM1 and the second semiconductor layer ACT2 and coupling between the third lower metal LM3 and the second semiconductor layer ACT2 may be prevented or reduced.

According to some embodiments, the display apparatus capable of displaying high-quality images is provided.

Effects of the disclosure are not limited to the above mentioned effects and other effects not mentioned may be clearly understood by those of ordinary skill in the art from the following claims.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

It should be understood that embodiments described herein should be considered in a descriptive sense only and not for purposes of limitation. Descriptions of features or aspects within each embodiment should typically be considered as available for other similar features or aspects in other embodiments. While some embodiments have been described with reference to the figures, it will be understood by those of ordinary skill in the art that various suitable changes in form and details may be made therein without departing from the spirit and scope of the present disclosure as defined by the following claims and their equivalents.

What is claimed is:

1. A display apparatus comprising:
a first sub-pixel comprising a first lower metal, a first semiconductor layer on the first lower metal, and a first upper metal on the first semiconductor layer;
a second sub-pixel comprising a second lower metal, a second semiconductor layer on the second lower metal, and a second upper metal on the second semiconductor layer; and
a third sub-pixel comprising a third lower metal, a third semiconductor layer on the third lower metal, and a third upper metal on the third semiconductor layer,
wherein an interval between the second lower metal and the first semiconductor layer is greater than an interval between the second semiconductor layer and the first semiconductor layer in a plan view, and
wherein the first sub-pixel, the second sub-pixel, and the third sub-pixel configured to display light of different colors.

2. The display apparatus of claim 1, wherein the interval between the second lower metal and the first semiconductor layer is less than an interval between the second lower metal and the first lower metal.

3. The display apparatus of claim 1, wherein the first lower metal, the second lower metal, and the third lower metal are arranged side-by-side in a second direction perpendicular to a first direction.

4. The display apparatus of claim 3, wherein the first sub-pixel further comprises a first pixel electrode, the second sub-pixel further comprises a second pixel electrode, and the third sub-pixel further comprises a third pixel electrode, and
wherein the second pixel electrode partially overlaps at least one of the first lower metal and the third lower metal.

5. The display apparatus of claim 4, wherein the first pixel electrode, the second pixel electrode, and the third pixel electrode are arranged side-by-side in a third direction crossing the first direction and the second direction.

6. The display apparatus of claim 4, wherein the first pixel electrode is electrically connected to the first semiconductor layer through a first contact hole,
wherein the second pixel electrode is electrically connected to the second semiconductor layer through a second contact hole, and
wherein the third pixel electrode is electrically connected to the third semiconductor layer through a third contact hole.

7. The display apparatus of claim 3, wherein the second lower metal is electrically connected to a gate connection line through a fourth contact hole, and the gate connection line is surrounded by the second semiconductor layer.

8. The display apparatus of claim 7, wherein the first to third upper metals and the gate connection line are at a same layer.

9. The display apparatus of claim 3, wherein the first upper metal at least partially overlaps the first lower metal and the first semiconductor layer,
wherein the second upper metal at least partially overlaps the second lower metal and the second semiconductor layer, and
wherein the third upper metal at least partially overlaps the third lower metal and the third semiconductor layer.

10. The display apparatus of claim 9, wherein each of the first to third upper metals extends in the second direction, and
wherein one end of at least one of the first to third upper metals extends in the first direction.

11. The display apparatus of claim 1, wherein an interval between the second lower metal and the third semiconductor layer is greater than an interval between the second semiconductor layer and the third semiconductor layer and less than an interval between the second lower metal and the third lower metal.

12. The display apparatus of claim 1, wherein each of the first to third lower metals has a gate electrode of a driving transistor.

13. The display apparatus of claim 1, wherein the first upper metal is electrically connected to the first semiconductor layer through a fifth contact hole,
wherein the second upper metal is electrically connected to the second semiconductor layer through a sixth contact hole, and
wherein the third upper metal is electrically connected to the third semiconductor layer through a seventh contact hole.

14. The display apparatus of claim 1, wherein the first sub-pixel further comprises a first sub-lower metal arranged between the first lower metal and the second lower metal and electrically connected to the first semiconductor layer, and
wherein the third sub-pixel further comprises a third sub-lower metal arranged between the second lower metal and the third lower metal and electrically connected to the third semiconductor layer.

15. A display apparatus comprising:
a first sub-pixel comprises a first lower metal having a gate electrode of a first driving transistor, and a first semiconductor layer on the first lower metal;
a second sub-pixel comprises a second lower metal having a gate electrode of a second driving transistor, and a second semiconductor layer on the second lower metal;
a third sub-pixel comprises a third lower metal having a gate electrode of a third driving transistor, and a third semiconductor layer on the third lower metal,
wherein the first sub-pixel, the second sub-pixel, and the third sub-pixel configured to respectively display light of different colors,
wherein the first to third lower metals are arranged side-by-side in a second direction perpendicular to a first direction, and
wherein a width in the second direction of the second lower metal is less than a width in the second direction of the second semiconductor layer.

16. The display apparatus of claim 15, wherein the second lower metal is electrically connected to a gate connection line through a fourth contact hole, the gate connection line being surrounded by the second semiconductor layer.

17. The display apparatus of claim 15, wherein the first sub-pixel further comprises a first pixel electrode, the second sub-pixel further comprises a second pixel electrode, and the third sub-pixel further comprises a third pixel electrode, and
wherein the second pixel electrode partially overlaps at least one of the first lower metal and the third lower metal.

18. The display apparatus of claim 17, wherein the first sub-pixel further comprises a first sub-lower metal arranged between the first lower metal and the second lower metal and electrically connected to the first pixel electrode, and
wherein the third sub-pixel further comprises a third sub-lower metal arranged between the second lower metal and the third lower metal and electrically connected to the second pixel electrode.

19. The display apparatus of claim 15, wherein the first sub-pixel further comprises a first upper metal partially overlapping the gate electrode of the first driving transistor and on the first semiconductor layer,
wherein the second sub-pixel further comprises a second upper metal partially overlapping the gate electrode of the second driving transistor and on the second semiconductor layer, and
wherein the third sub-pixel further comprises a third upper metal partially overlapping the gate electrode of the third driving transistor and on the third semiconductor layer.

20. The display apparatus of claim 15, wherein a width in the second direction of the first lower metal is less than a width in the second direction of the first semiconductor layer, and
wherein a width in the second direction of the third lower metal is less than a width in the second direction of the third semiconductor layer.
